(19) United States
(12) Patent Application Publication
(10) Pub. No.: US 2025/0350097 A1
(43) Pub. Date: Nov. 13, 2025

(54) ADDRESSABLE VERTICAL CAVITY SURFACE EMITTING LASER APPARATUS

(71) Applicant: Lumentum Operations LLC, San Jose, CA (US)

(72) Inventors: Yeyu ZHU, San Jose, CA (US); Yuefa LI, San Jose, CA (US)

(21) Appl. No.: 18/829,951

(22) Filed: Sep. 10, 2024

Related U.S. Application Data
(60) Provisional application No. 63/643,672, filed on May 7, 2024.

(51) Int. Cl. H01S 5/42; H01S 5/02; H01S 5/026; H01S 5/028; H01S 5/183

(52) U.S. Cl. CPC H01S 5/423; H01S 5/0261; H01S 5/0282; H01S 5/18341; H01S 5/18344; H01S 5/0201

(57) ABSTRACT

In some implementations, a vertical cavity surface emitting laser (VCSEL) device may include a substrate, and a set of epitaxial layers, disposed on the substrate, defining a plurality of VCSEL mesa structures, where each of the plurality of VCSEL mesa structures has a top surface and a sidewall. The VCSEL device may include an additional layer structure disposed on the set of epitaxial layers, where the additional layer structure configures the plurality of VCSEL mesa structures into a set of emitting VCSEL structures, for backside emission through the substrate, and a set of non-emitting VCSEL structures. The additional layer structure may include a first contact layer on the set of epitaxial layers at a base of the plurality of VCSEL mesa structures and surrounding each of the plurality of VCSEL mesa structures, and a second contact layer on top surfaces of the set of emitting VCSEL structures.

### CROSS-REFERENCE TO RELATED APPLICATION

This Patent Application claims priority to U.S. Provisional Patent Application No. 63/643,672, filed on May 7, 2024, and entitled “DENSE MATRIX ADDRESSABLE VERTICAL CAVITY SURFACE EMITTING LASER ARRAY.” The disclosure of the prior Application is considered part of and is incorporated by reference into this Patent Application.

### TECHNICAL FIELD

The present disclosure relates generally to lasers and to an addressable vertical cavity surface emitting laser (VCSEL) apparatus.

### BACKGROUND

A vertical-emitting laser device, such as a VCSEL, is a laser in which a beam is emitted in a direction perpendicular to a surface of a substrate (e.g., vertically from a surface of a semiconductor wafer). Multiple vertical-emitting devices may be arranged in an array with a common substrate.

### SUMMARY

Some implementations described herein relate to a VCSEL device. The VCSEL device may include a substrate, and a set of epitaxial layers, disposed on the substrate, defining a plurality of VCSEL mesa structures, where each of the plurality of VCSEL mesa structures has a top surface and a sidewall. The VCSEL device may include an additional layer structure disposed on the set of epitaxial layers, where the additional layer structure configures the plurality of VCSEL mesa structures into a set of emitting VCSEL structures, for backside emission through the substrate, and a set of non-emitting VCSEL structures. The additional layer structure may include a first contact layer on the set of epitaxial layers at a base of the plurality of VCSEL mesa structures and surrounding each of the plurality of VCSEL mesa structures, and a second contact layer on top surfaces of the set of emitting VCSEL structures. The additional layer structure may have a first layer composition, for the set of emitting VCSEL structures, that allows current flow between the first contact layer and the second contact layer through the set of epitaxial layers. The additional layer structure may have a second layer composition, for the set of non-emitting VCSEL structures, that allows current flow over top surfaces of the non-emitting VCSEL structures to the first contact layer and disallows current flow through the set of epitaxial layers.

Some implementations described herein relate to an addressable VCSEL apparatus. The addressable VCSEL apparatus may include a VCSEL device including a substrate and a set of epitaxial layers, disposed on the substrate, defining a plurality of VCSEL mesa structures. The VCSEL device may include an additional layer structure disposed on the set of epitaxial layers, where the additional layer structure configures the plurality of VCSEL mesa structures into a set of emitting VCSEL structures, for backside emission through the substrate, and a set of non-emitting VCSEL structures. The VCSEL device may include a plurality of VCSEL interconnects electrically connected to one or more plating layers of the additional layer structure on respective top surfaces of the set of emitting VCSEL structures and the set of non-emitting VCSEL structures. The plurality of VCSEL interconnects and the one or more plating layers may define respective electrodes for the set of emitting VCSEL structures and respective opposite electrodes for the set of non-emitting VCSEL structures. The VCSEL device may include a first dielectric covering the additional layer structure, where the plurality of VCSEL interconnects are exposed through openings in the first dielectric. The addressable VCSEL apparatus may include a driver device for the VCSEL device. The driver device may include a plurality of driver interconnects on a surface of the driver device. The driver device may include a second dielectric covering the surface, where the plurality of driver interconnects are exposed through openings in the second dielectric. The plurality of driver interconnects may be bonded to the plurality of VCSEL interconnects.

Some implementations described herein relate to a method. The method may include forming a plurality of VCSEL interconnects on one or more plating layers of an additional layer structure disposed on a plurality of VCSEL mesa structures of a plurality of VCSEL devices of a VCSEL wafer. The additional layer structure may configure the plurality of VCSEL mesa structures into a set of emitting VCSEL structures and a set of non-emitting VCSEL structures. The plurality of VCSEL interconnects and the one or more plating layers may define respective electrodes for the set of emitting VCSEL structures and respective opposite electrodes for the set of non-emitting VCSEL structures. The method may include depositing a first dielectric on the plurality of VCSEL devices, and a second dielectric on a plurality of driver devices of a driver wafer. The method may include planarizing the first dielectric to expose the plurality of VCSEL interconnects through the first dielectric, and the second dielectric to expose a plurality of driver interconnects, of the plurality of driver devices, through the second dielectric. The method may include bonding the VCSEL wafer to the driver wafer to obtain a bonded VCSEL wafer and driver wafer, wherein the plurality of VCSEL interconnects are bonded to the plurality of driver interconnects in the bonded VCSEL wafer and driver wafer.

### BRIEF DESCRIPTION OF THE DRAWINGS

FIG. 1 illustrates an example VCSEL mesa structure.

FIGS. 2A-2B illustrate an example VCSEL device.

FIG. 3 illustrates an example addressable VCSEL apparatus.

FIG. 4 illustrates examples of locations of through silicon vias and electrical contacts.

FIG. 5 is a diagram illustrating an example process associated with manufacturing a VCSEL apparatus.

### DETAILED DESCRIPTION

The following detailed description of example implementations refers to the accompanying drawings. The same reference numbers in different drawings may identify the same or similar elements.

In an addressable vertical cavity surface emitting laser (VCSEL) array, subarrays of VCSELs may be individually activated (e.g., turned on), which may be useful in light detection and ranging (lidar) applications, three-dimensional sensing applications, or the like. For example, cathode contacts may connect the VCSELs over a row and anode contacts may connect the VCSELs down a column. By applying a positive voltage to a particular column and a negative voltage to a particular row, a VCSEL at the intersection can be activated. Because each VCSEL may share a cathode contact with other VCSELs in the same row and share an anode contact with other VCSELs in the same column, rather than having its own contacts, an addressing capability for the VCSEL array may be limited. In a top-emitting VCSEL configuration, a top surface of a VCSEL chip may include emission areas of the VCSELs. Furthermore, the top surface may be used for routing anode and cathode traces, which should be arranged so as not to block the emission areas of the VCSELs. These constraints produce a complex design that limits minimum VCSEL pitches and increases overall chip size significantly beyond an emission area of the VCSEL chip.

A VCSEL chip with a VCSEL array may be mounted directly on a driver chip for the VCSEL chip, in a configuration known as VCSEL on driver (VOD). VOD manufacturing processes may be performed at the chip level. For example, an individual VCSEL chip may be combined with an individual driver chip and mechanically supported using an underfill process that fills a gap between the VCSEL chip and the driver chip with an underfill material. This process makes it difficult to manufacture VODs with small VCSEL chips (e.g., due to pick and place challenges). Moreover, manufacturing at the chip level is inefficient, resulting in low manufacturing yields.

Some implementations described herein relate to a VCSEL device (e.g., a VCSEL chip) that enables individual VCSEL addressability while achieving high emitter density and enhanced electrical performance. In some implementations, the VCSEL device may use a backside emitting configuration, thereby allowing anode and cathode contacts for the VCSEL device to be located on an opposite surface from emission areas, allowing for reduced VCSEL pitch. Moreover, the backside emitting configuration may facilitate flip-chip bonding (e.g., to realize shorter interconnect distances relative to wire bonding), high packaging density, reduced parasitic capacitance, or the like.

In some implementations, the VCSEL device may include a substrate and a set of epitaxial layers on the substrate that define a plurality of VCSEL mesa structures.

Additionally, the VCSEL device may include an additional layer structure disposed on the set of epitaxial layers. The additional layer structure may configure the VCSEL mesa structures into a set of emitting VCSEL structures (e.g., that are capable of laser light emission) and a set of non-emitting VCSEL structures (e.g., that are incapable of laser light emission). For example, the additional layer structure may have different compositions (e.g., different configurations of layers, or different configurations of the same layers) for the emitting VCSEL structures and for the non-emitting VCSEL structures. The particular composition of the additional layer structure over a VCSEL mesa structure defines whether that VCSEL mesa structure is an emitting VCSEL structure or a non-emitting VCSEL structure.

For both emitting VCSEL structures and non-emitting VCSEL structures, the additional layer structure may include a first contact layer (e.g., a cathode contact) that is disposed at a base of the VCSEL mesa structures and that surrounds each of the VCSEL mesa structures. Moreover, the additional layer structure may include a second contact layer (e.g., an anode contact) on top surfaces of the emitting VCSEL structures. For the emitting VCSEL structures, the additional layer structure may have a first layer composition that allows current flow between the first contact layer and the second contact layer through the set of epitaxial layers (e.g., from the second contact layer through the set of epitaxial layers to the first contact layer). For the non-emitting VCSEL structures, the additional layer structure may have a second layer composition that allows current flow over top surfaces of the non-emitting VCSEL structures to the first contact layer but disallows (e.g., through the use of a passivation layer) current flow through the set of epitaxial layers. Rather, the non-emitting VCSEL structures may provide an electrical connection path (e.g., cathode connectivity) to the first contact layer from the top surfaces of the non-emitting VCSEL structures (e.g., around the VCSEL mesa structures of the non-emitting VCSEL structures instead of through the VCSEL mesa structures).

The first contact layer may be positioned very near to the sidewalls of the VCSEL mesa structures, with only a small gap between sidewalls of the VCSEL mesa structures and the first contact layer (e.g., which may be dictated by photoresist lithography constraints). This arrangement of the first contact layer improves a performance of the VCSEL device, such as by reducing electrical resistance and improving uniformity across the VCSEL array (e.g., relative to a contact layer located outside of an emitter array area).

A plurality of interconnects (e.g., copper posts) may be connected to the additional layer structure through the second layer on top of the VCSEL mesa structures or may be part of the additional layer structure (e.g., part of the second layer). The interconnects may provide electrical connectivity into the VCSEL device. The interconnects may be provided at a same height across the VCSEL device to aid flip-chip configuration, planarization, and wafer bonding as described in more detail below. In some implementations, each emitting VCSEL structure includes an interconnect (e.g. for individual addressability) while some or all of the non-emitting VCSEL structures include interconnects (e.g., for electrical connectivity into the first contact layer).

Following formation of interconnects on a VCSEL wafer (e.g., that includes a plurality of VCSEL devices), a dielectric layer may be deposited on the VCSEL wafer. For example, for a plurality of VCSEL devices in a VCSEL wafer, dielectric may fill between the emitting and non-emitting VCSEL structures and over the interconnects. Deposition of the dielectric layer may include multiple iterations of applying a spin on glass (SOG) coat and curing until the uppermost (e.g. highest or tallest) structures on the wafer are covered. Furthermore, the manufacturing process may include planarizing the dielectric layer on the VCSEL wafer to expose the top surface contacts of the VCSEL devices in the VCSEL wafer.

In some implementations, a VCSEL apparatus may integrate the VCSEL device with a driver device (e.g., a driver chip) in a VOD configuration. The driver device may be electrically connected to the VCSEL device by the plurality of interconnects (e.g., copper posts) that connect to each of the emitting VCSEL structures (e.g., for individual addressability) and at least some of the non-emitting VCSEL structures of the VCSEL device. In operation, to activate an emitting VCSEL structure, the driver device may cause current to flow, via the interconnect connected to the emitting VCSEL structure, into the epitaxial layers of the emitting VCSEL structure and to the contact layer. From the contact layer, the current may flow across the top of a non-emitting VCSEL structure (e.g., without flowing into the epitaxial layers of the non-emitting VCSEL structure) and back to the driver device via the interconnect of the non-emitting VCSEL structure. To operate multiple emitting VCSEL structures, the driver device may cause current to flow, via the interconnect, to multiple emitting VCSEL structures.

In connection with the driver device, following formation of interconnects on a driver wafer (e.g., that includes a plurality of driver devices), a dielectric layer may be deposited on the driver wafer. For example, for the driver wafer, the dielectric may fill over interconnects and between any redistribution layers or other structures. Deposition of the dielectric layer may include multiple iterations of applying an SOG coat and curing until the uppermost (e.g. highest or tallest) structures on the wafer are covered. Furthermore, the manufacturing process may include planarizing the dielectric layer on the driver wafer to expose the interconnects of the driver devices in the driver wafer.

A planarized VCSEL wafer and driver wafer may be bonded together before being singulated into multiple VCSEL apparatuses. Thus, an area between each VCSEL device and driver device may be filled with a dielectric material to provide mechanical support between the VCSEL device and the driver device. Relative to an underfill material that provides poor coefficient of thermal expansion (CTE) matching between the VCSEL device and the driver device, the dielectric material may provide improved CTE matching between the VCSEL device and the driver device, thereby reducing stress in the VCSEL apparatus and improving manufacturing yield. Moreover, rather than using a complex and inefficient die level underfilling, the steps of depositing and planarizing the dielectric layers simplifies the manufacturing process and enables wafer level bonding that improves manufacturing yield. Furthermore, the wafer level processing of the manufacturing process is suitable for producing both small and large VCSEL devices (e.g., by eliminating pick and place constraints). Thus, use of the dielectric material may facilitate wafer-level processing for the VCSEL apparatus, the VCSEL device, and/or the driver device.

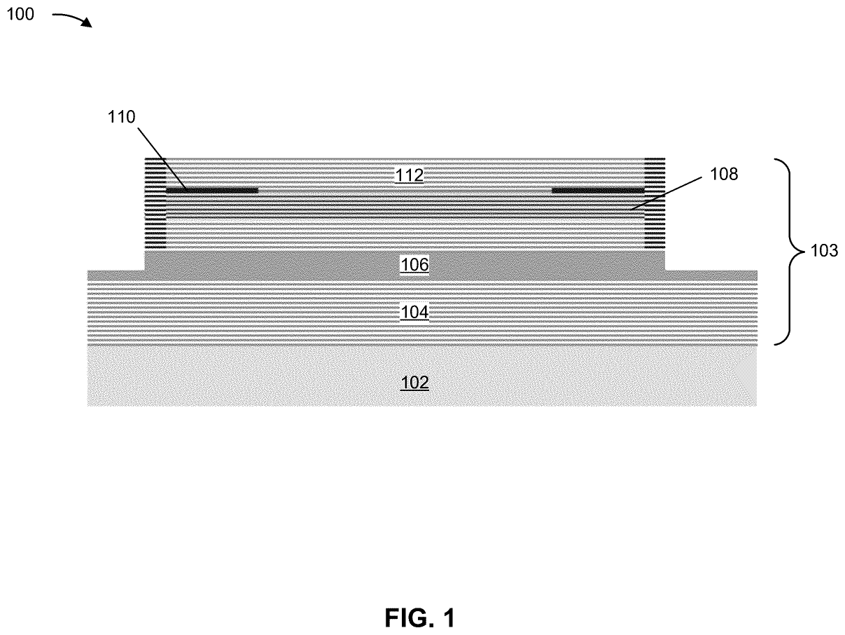

FIG. 1 illustrates an example VCSEL mesa structure 100. In some implementations, the VCSEL mesa structure 100 may be included in an array of VCSEL mesa structures 100 within a VCSEL device, as described herein. In some implementations, the VCSEL mesa structure 100 may be used for a backside-emitting (also referred to as “back emitting” or “bottom emitting”) emitter, as described herein. As shown in FIG. 1, the VCSEL mesa structure 100 may include a substrate 102 and a set of epitaxial layers 103 disposed on the substrate 102. The set of epitaxial layers 103 may include a bottom mirror structure 104, a contact buffer layer 106 (e.g., in the bottom mirror structure 104), a cavity including one or more active regions (herein referred to as cavity region 108), a confinement layer 110 that forms a confinement aperture, and/or a top mirror structure 112.

The VCSEL mesa structure 100 may project from the contact buffer layer 106, as shown. The VCSEL mesa structure 100 has a top surface (e.g., a top surface of the top mirror structure 112) and a sidewall extending between the contact buffer layer 106 and the top surface.

Substrate 102 includes a supporting material upon which, or within which, one or more layers or features of the VCSEL mesa structure 100 are grown or fabricated. In some implementations, the substrate 102 includes an n-type material. In some implementations, the substrate 102 includes a semi-insulating type of material. In some implementations, the semi-insulating type of material may be used in order to reduce optical absorption from the substrate 102. In some implementations, the substrate 102 may be formed from a semiconductor material, such as gallium arsenide (GaAs), indium phosphide (InP), or another type of semiconductor material. In some implementations, a back side of the substrate 102 (e.g., opposite the side of the substrate 102 supporting the epitaxial layers 103) may be coated with an anti-reflection coating (ARC).

Bottom mirror structure 104 is a bottom reflector of an optical resonator of the VCSEL mesa structure 100. For example, the bottom mirror structure 104 may include a distributed Bragg reflector (DBR), a dielectric mirror, or another type of mirror structure. In some implementations, the bottom mirror structure 104 is formed from an n-type material. In some implementations, the bottom mirror structure 104 is on a top surface of the substrate 102. In some implementations, the bottom mirror structure 104 includes a set of layers (e.g., aluminum gallium arsenide (AlGaAs) layers) grown using a metal-organic chemical vapor deposition (MOCVD) technique, a molecular beam epitaxy (MBE) technique, or another technique. The contact buffer layer 106 (e.g., in the bottom mirror structure 104) may be an ohmic contact layer and/or an electrically conductive contact layer. In some implementations, the contact buffer layer 106 is formed from an n-type material.

Cavity region 108 includes one or more layers where electrons and holes recombine to emit light and define the emission wavelength range of the VCSEL mesa structure 100. For example, the cavity region 108 may include one or more active regions in the form of one or more quantum wells (QWs). An optical thickness of the cavity region 108, the top mirror structure 112, and the bottom mirror structure 104 defines the resonant cavity wavelength of the VCSEL mesa structure 100, which may be designed within an emission wavelength range of the cavity region 108 to enable lasing. In some implementations, the cavity region 108 may be formed on the bottom mirror structure 104. In some implementations, the cavity region 108 includes a set of layers grown using an MOCVD technique, an MBE technique, or another technique.

Confinement layer 110 is a layer that provides optical and/or electrical confinement for the VCSEL mesa structure 100. In some implementations, the confinement layer 110 enhances carrier and mode confinement of the VCSEL mesa structure 100 and, therefore, can improve performance of the VCSEL mesa structure 100. In some implementations, the confinement layer 110 is on, under, or in the cavity region 108. In some implementations, there may be one or more spacer layers or mirror layers (e.g., DBRs) between the confinement layer 110 and the cavity region 108. In some implementations, the confinement layer 110 is on a side of the cavity region 108 nearer to the bottom mirror structure 104 (i.e., on a substrate side of the cavity region 108). In some implementations, the confinement layer 110 is on a side of the cavity region 108 nearer to the top mirror structure 112 (i.e., on a non-substrate side of the cavity region 108).

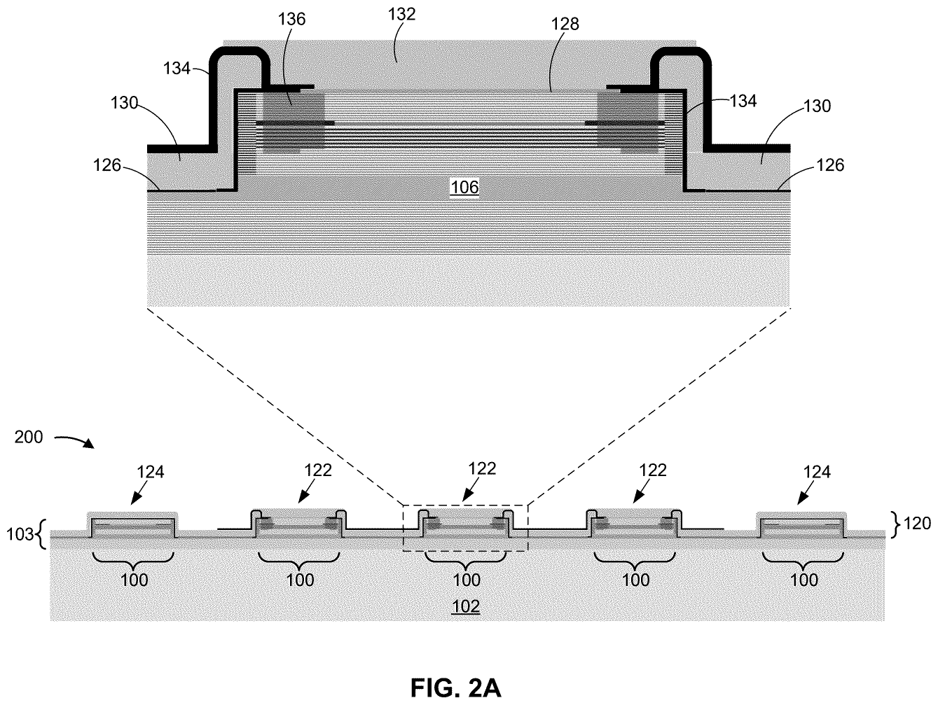

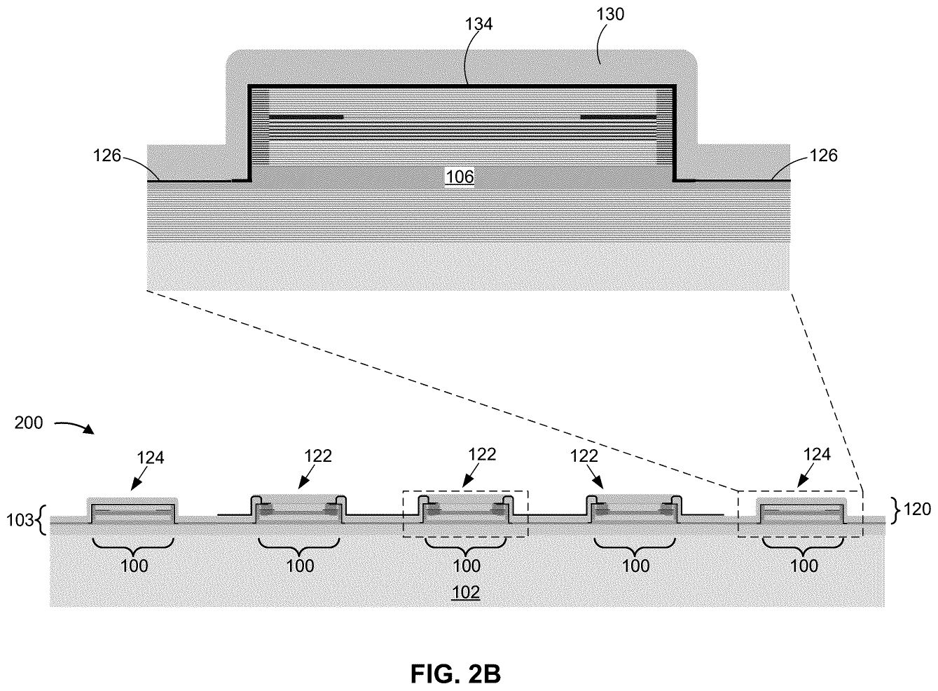

In some implementations, the confinement layer 110 is an oxide layer formed as a result of oxidation of one or more epitaxial layers of the VCSEL mesa structure 100. For example, the confinement layer 110 may be an aluminum oxide (Al₂O₃) layer formed as a result of oxidation of an epitaxial layer (e.g., an AlGaAs layer, an AlAs layer, or the like). In some implementations, oxidation trenches (that define the mesa structure of the VCSEL mesa structure 100, as described further in connection with FIG. 2A) etched around the VCSEL mesa structure 100 may allow steam to access epitaxial layer(s) 103 from which the confinement layer 110 is formed. In some implementations, the confinement layer 110 defines a confinement aperture of the VCSEL mesa structure 100.

Top mirror structure 112 is a top reflector of the optical resonator of the VCSEL mesa structure 100. For example, the top mirror structure 112 may include a DBR, a dielectric mirror, or the like. In some implementations, the top mirror structure 112 is formed from a p-type material. In some implementations, the top mirror structure 112 includes a set of layers (e.g., AlGaAs layers) grown using an MOCVD technique, an MBE technique, or another technique. In some implementations, the top mirror structure 112 is grown on or over the cavity region 108.

The number, arrangement, thicknesses, order, symmetry, or the like, of layers shown in FIG. 1 are provided as an example. In practice, the VCSEL mesa structure 100 may include additional layers, fewer layers, different layers, differently constructed layers, or differently arranged layers than those shown in FIG. 1. Additionally, or alternatively, a set of layers (e.g., one or more layers) of the VCSEL mesa structure 100 may perform one or more functions described as being performed by another set of layers of the VCSEL mesa structure 100, and any layer may include more than one layer.

FIGS. 2A-2B illustrate an example VCSEL device 200. For example, the VCSEL device 200 may be a VCSEL chip. As shown, the set of epitaxial layers 103, on the substrate 102, may define a plurality of VCSEL mesa structures 100 (e.g., an array of VCSEL mesa structures 100). Moreover, the VCSEL device 200 may include an additional layer structure 120 disposed on the set of epitaxial layers 103. The additional layer structure 120 may configure the VCSEL mesa structures 100 into a set of emitting VCSEL structures 122 (configured for backside emission through the substrate 102) and a set of non-emitting VCSEL structures 124. The set of emitting VCSEL structures 122 may include one or more emitting VCSEL structures 122, and the set of non-emitting VCSEL structures 124 may include one or more non-emitting VCSEL structures 124. An emitting VCSEL structure 122 may be capable of laser light emission, whereas a non-emitting VCSEL structure 124 may be incapable of laser light emission. The locations of the emitting VCSEL structures 122 may define an “emission region” of the VCSEL device 200, and the locations of the non-emitting VCSEL structures 124 may define a “connection region” of the VCSEL device 200.

The additional layer structure 120 has different compositions for the emitting VCSEL structures 122 and for the non-emitting VCSEL structures 124, where the particular composition of the additional layer structure 120 over a VCSEL mesa structure 100 defines whether that VCSEL mesa structure 100 is an emitting VCSEL structure 122 or a non-emitting VCSEL structure 124. As shown in FIGS. 2A and 2B, for both emitting VCSEL structures 122 and non-emitting VCSEL structures 124, the additional layer structure 120 may include a first contact layer 126 that is disposed on, and electrically connected to, the set of epitaxial layers 103 at a base of the VCSEL mesa structures 100 (e.g., on the contact buffer layer 106), and that surrounds each of the VCSEL mesa structures 100 (e.g., each of the VCSEL mesa structures 100 project through openings in the first contact layer 126).

Accordingly, the first contact layer 126 is located within the emission region (e.g., the emitter array area) of the VCSEL device 200, rather than being located outside of the emission region (e.g., at a chip edge). The first contact layer 126 may be positioned very near to the sidewalls of the VCSEL mesa structures 100, with only a small gap between sidewalls of the VCSEL mesa structures 100 and the first contact layer 126 that may be dictated by manufacturing (e.g., photoresist lithography) constraints. For example, a minimum separation between the first contact layer 126 and sidewalls of the VCSEL mesa structures 100 may be less than a pitch of the VCSEL mesa structures. As an example, a gap between the first contact layer 126 and sidewalls of the VCSEL mesa structures 100 may be at most 3 micrometers (μm) or at most 2 μm.

In some implementations, the first contact layer 126 is formed from an n-type material. For example, the first contact layer 126 may be an n-Ohmic metal. The first contact layer 126 may make electrical contact with the contact buffer layer 106. In some implementations, the first contact layer 126 serves as a cathode (e.g., a common cathode) for the emitting VCSEL structures 122. In some implementations, the first contact layer 126 may include an annealed metallization layer, such as a gold-germanium-nickel (AuGeNi) layer or a palladium-germanium-gold (PdGeAu) layer, among other examples.

As shown in FIG. 2A, for the emitting VCSEL structures 122, the additional layer structure 120 may have a first layer composition that allows current flow through the set of epitaxial layers 103 to the first contact layer 126 (e.g., via the contact buffer layer 106). In the first layer composition, the additional layer structure 120 may include the first contact layer 126 on the set of epitaxial layers 103 at the base of the VCSEL mesa structures 100 (e.g., on the contact buffer layer 106), a second contact layer 128 on top surfaces of the set of emitting VCSEL structures 122 and electrically connected to the set of epitaxial layers 103, a first plating layer 130 on the first contact layer 126, a second plating layer 132 on the second contact layer 128, and one or more passivation layers 134 that provide electrical isolation, such as isolating the first plating layer 130 from the set of epitaxial layers 103 and/or isolating the first plating layer 130 from the second plating layer 132. The first contact layer 126 and the second contact layer 128 may have opposite conductivities from each other. In this way, current may flow from the second plating layer 132 and the second contact layer 128 (at the top surfaces of the set of emitting VCSEL structures 122), through the set of epitaxial layers 103, to the first contact layer 126 (e.g., via the contact buffer layer 106).

In some implementations, the emitting VCSEL structures 122 may be manufactured by depositing the second contact layer 128 on the set of epitaxial layers 103 (e.g., before the etching that defines the mesa structures of the VCSEL mesa structures 100). Next, trenches may be etched down to the contact buffer layer 106, thereby forming the mesas of the VCSEL mesa structures 100 and facilitating completion of oxidation of the confinement layer 110. A passivation layer 134 may then be deposited over the second contact layer 128 and the epitaxial layers 103. Following deposition of the passivation layer 134, the passivation layer 134 may be etched (e.g., dielectric film etching) to expose the contact buffer layer 106, the sidewalls of the VCSEL mesa structures 100, and a perimeter portion of the top surfaces of the VCSEL mesa structures 100 (e.g., which may be done to ensure removal of the passivation layer 134 from the sidewalls). Removal of the passivation layer 134 from the sidewalls of the VCSEL mesa structures 100 allows the first contact layer 126 to be deposited in close proximity to the sidewalls of the VCSEL mesa structures 100. Thus, the first contact layer 126 may be deposited on the exposed contact buffer layer 106, thereby positioning the first contact layer 126 in close proximity to the sidewalls of the VCSEL mesa structures 100 (e.g., thereby reducing electrical resistance and enabling high emitter density). An additional passivation layer 134 may be deposited, to at least cover the sidewalls of the VCSEL mesa structures 100 (e.g., to provide isolation between the sidewalls of the VCSEL mesa structures 100 and the first contact layer 126), and the additional passivation layer 134 may be opened over the first contact layer 126 and the second contact layer 128. Next, the first plating layer 130 may be applied over the first contact layer 126, and an additional passivation layer 134 is deposited, thereby sealing the first plating layer 130. This additional passivation layer 134 is etched to expose the second contact layer 128. Thereafter, the second plating layer 132 is applied. In some implementations, an isolation implant 136 may be implanted into the epitaxial layers 103 during manufacturing of the emitting VCSEL structures 122 (e.g., after applying the second plating layer 132). In some implementations, the application or removal of the passivation layers 134 may be different than as described above, provided that the passivation layers 134 isolate the first plating layer 130 from the set of epitaxial layers 103 and isolate the first plating layer 130 from the second plating layer 132.

In some implementations, the second contact layer 128 is formed from a p-type material. For example, the second contact layer 128 may be a p-Ohmic metal. The second contact layer 128 may make electrical contact with the top mirror structure 112 through which current may flow. In some implementations, the second contact layer 128 serves as anodes for the emitting VCSEL structures 122. In this way, each emitting VCSEL structure 122 has its own anode contact, thereby facilitating individual control of the emitting VCSEL structures 122. In some implementations, the second contact layer 128 includes an annealed metallization layer. For example, the second contact layer 128 may include a chromium-gold (Cr—Au) layer, a gold-zinc (Au—Zn), a titanium-platinum-gold (TiPtAu) layer, a gold-germanium-nickel (AuGeNi) layer, or a palladium-germanium-gold (PdGeAu) layer, among other examples.

In some implementations, the first plating layer 130 is formed from an n-type material (e.g., an n-type metal). The first plating layer 130 may make electrical contact with the first contact layer 126. In some implementations, the second plating layer 132 is formed from a p-type material (e.g., a p-type metal). The second plating layer 132 may make electrical contact with the second contact layer 128.

A passivation layer 134 may be a dielectric layer. A passivation layer 134 may provide at least partial insulation between adjacent structures. In some implementations, a passivation layer 134 may include, for example, silicon nitride (SiN), silicon dioxide (SiO₂), a polymer dielectric, or another type of insulating material.

Isolation implant 136 is a region to prevent free carriers from reaching edges of trenches (e.g., preventing an electrical short or reducing current leakage). Isolation implant 136 may include, for example, an ion implanted material, such as a hydrogen/proton implanted material or a similar implanted element to reduce conductivity.

As shown in FIG. 2B, for the non-emitting VCSEL structures 124, the additional layer structure 120 may have a second layer composition that allows current flow over top surfaces of the non-emitting VCSEL structures 124 to the first contact layer but disallows (e.g., blocks) current flow through the set of epitaxial layers 103 to the first contact layer 126. In the second layer composition, the additional layer structure 120 may include the first contact layer 126 on the set of epitaxial layers 103 at the base of the VCSEL mesa structures 100 (e.g., on the contact buffer layer 106), the first plating layer 130 (or the second plating layer 132, as described below) on the first contact layer 126 and extending over top surfaces of the non-emitting VCSEL structures 124, and one or more passivation layers 134 isolating the first plating layer 130 from the set of epitaxial layers 103.

In some implementations, the non-emitting VCSEL structures 124 may be manufactured concurrently (e.g., in concert for manufacturing efficiency) with manufacturing of the emitting VCSEL structures 122. Thus, the application of a passivation layer 134, the etching to form the mesa structures of the VCSEL mesa structures 100, and the deposition of the first contact layer 126, described above, may also be performed with respect to the non-emitting VCSEL structures 124 (e.g., as part of the same processing steps performed with respect to the emitting VCSEL structures 122). In some implementations, the deposition of the second contact layer 128, described above, may not be performed, or may be removed from, the non-emitting VCSEL structures 124. In addition, one or more passivation layers 134 that are applied, as described above, may not be opened over the non-emitting VCSEL structures 124. Accordingly, one or more passivation layers 134 may cover an entirety of the non-emitting VCSEL structures 124 (e.g., over their top surfaces and sidewalls). The application of the first plating layer 130, described above, may also be performed with respect to the non-emitting VCSEL structures 124 (e.g., as part of the same processing steps performed with respect to the emitting VCSEL structures 122). However, with respect to the non-emitting VCSEL structures 124, the first plating layer 130 may be applied over the first contact layer 126 and over the passivation layer 134 covering the VCSEL mesa structures 100 (e.g., the first plating layer 130 may extend from the first contact layer 126 at a base of the VCSEL mesa structures 100, up the passivated sidewalls, and onto passivated top surfaces of the VCSEL mesa structures 100). In some implementations, the plating layer over the non-emitting VCSEL structures 124 may be a combination of the first plating layer 130 and the second plating layer 132, or the second plating layer 132 alone, to achieve particular manufacturing efficiencies. In some implementations, a passivation layer 134 applied in connection with manufacturing the emitting VCSEL structures 122 may be allowed to be applied over the first plating layer 130 of the non-emitting VCSEL structures 124, and such a passivation layer 134 may be removed from the non-emitting VCSEL structures 124 (e.g., at least at top surfaces of the non-emitting VCSEL structures 124). In some implementations, the application or removal of the passivation layers 134 may be different than as described above, provided that the passivation layers 134 isolate the first plating layer 130 from the set of epitaxial layers 103.

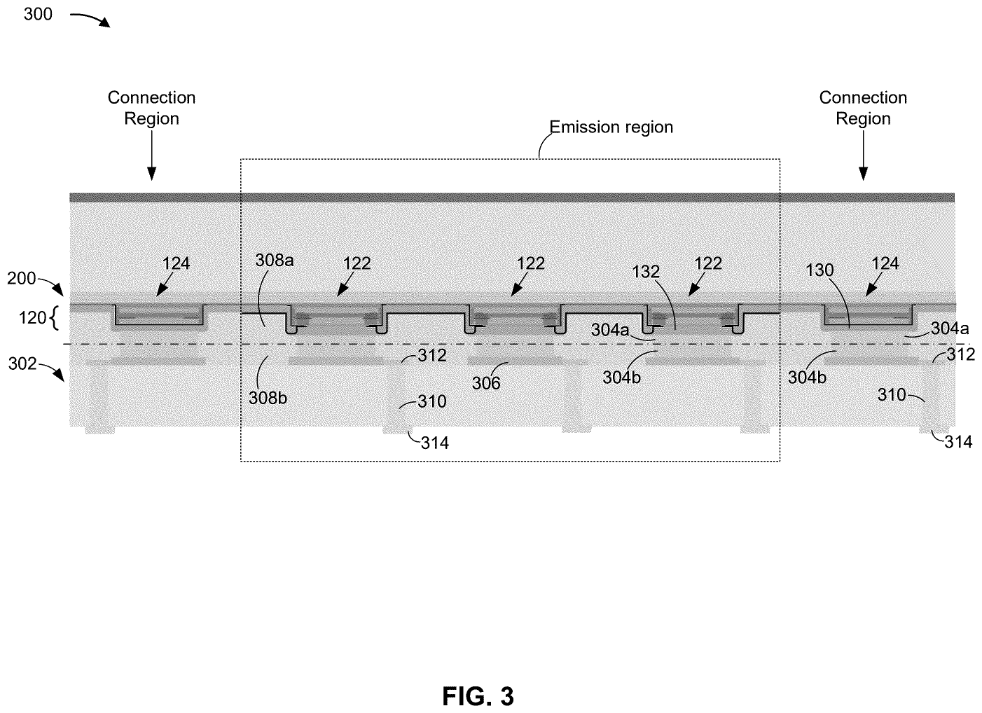

In this way, the non-emitting VCSEL structures 124 are electrically isolated, while the first plating layer 130 is shorted over the top surfaces of the non-emitting VCSEL structures 124 to provide an electrical connection path from the first contact layer 126 across the top surfaces of the non-emitting VCSEL structures 124. Accordingly, the non-emitting VCSEL structures 124 are in effect dummy VCSEL mesa structures that provide cathode connectivity (e.g., to a driver device, as described in connection with FIG. 3) without producing light emission. Moreover, concurrent manufacturing of the non-emitting VCSEL structures 124 with the emitting VCSEL structures 122 allows the non-emitting VCSEL structures 124 to have a similar height as the emitting VCSEL structures 122, thereby facilitating connection of the VCSEL device 200 to a driver device, as described in connection with FIG. 3. In some implementations, some non-emitting VCSEL structures 124 may be configured to provide cathode connectivity, while other non-emitting VCSEL structures 124 may be electrically isolated but not configured to provide cathode connectivity (e.g., isolation of each of the non-emitting VCSEL structures 124 may reduce power loss and avoid unwanted emissions).

While the VCSEL device 200 is described with a P-N-P configuration, in some implementations, the VCSEL device 200 may have an N-P-N configuration with the conductivities of the first contact layer 126, the second contact layer 128, the first plating layer 130, and the second plating layer 132 being reversed from the description herein. Additionally, or alternatively, while the VCSEL device 200 is described with a common cathode and individually addressable anodes, in some implementations, the VCSEL device 200 may employ a common anode and individually addressable cathodes.

As indicated above, FIGS. 2A-2B are provided as an example. Other examples may differ from what is described with regard to FIGS. 2A-2B.

FIG. 3 illustrates an example addressable VCSEL apparatus 300. The VCSEL apparatus 300 includes the VCSEL device 200 and a driver device 302 (e.g., a silicon driver, such as a complementary metal oxide semiconductor (CMOS) driver) for the VCSEL device 200. For example, the driver device 302 may be a driver chip. In some implementations, the VCSEL apparatus 300 may be incorporated into a time of flight (ToF) camera, a light detection and ranging (lidar) system, a three-dimensional sensing system, or the like.

As shown, in the VCSEL apparatus 300, the VCSEL device 200 may be stacked on the driver device 302 in a VOD configuration (e.g., using direct chip attachment). The configuration of the additional layer structure 120 for the emitting VCSEL structures 122 enables the driver device 302 to individually address (e.g., individually activate) the emitting VCSEL structures 122, rather than activating entire emitter rows or subarrays of the VCSEL device 200.

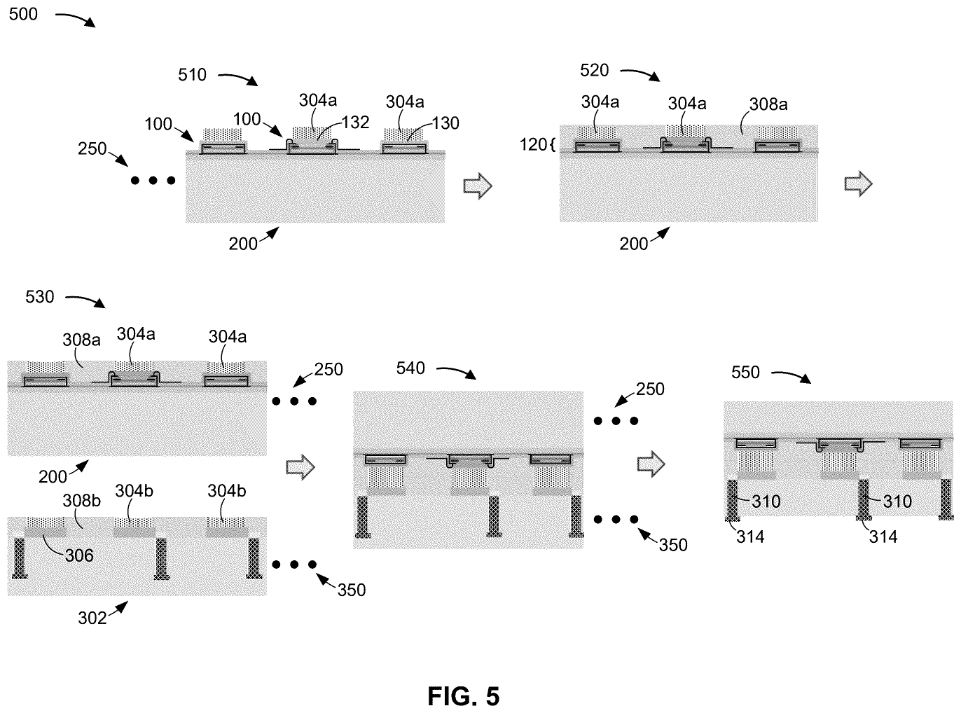

As shown, the VCSEL device 200 may include a plurality of VCSEL interconnects 304a (i.e., interconnects connected to the VCSEL device 200), such as copper posts (which may refer to posts or other-shaped interconnects that include copper and/or another metal). The VCSEL interconnects 304a may be electrically connected to one or more plating layers of the additional layer structure 120 on respective top surfaces of the emitting VCSEL structures 122 and the non-emitting VCSEL structures 124. For example, the VCSEL interconnects 304a that are on the set of emitting VCSEL structures 122 may be electrically connected to the second plating layer 132 of the additional layer structure 120, and the VCSEL interconnects 304a that are on the set of non-emitting VCSEL structures 124 may be electrically connected to the first plating layer 130 (and/or the second plating layer 132 if the second plating layer 132 is used in the second layer composition). The VCSEL interconnects 304a and the one or more plating layers of the additional layer structure 120 may define respective electrodes (e.g., anodes) for the emitting VCSEL structures 122 and respective opposite electrodes (e.g., cathodes) for the non-emitting VCSEL structures 124. A respective VCSEL interconnect 304a may be on each emitting VCSEL structure 122, thereby enabling individual addressability. In some implementations, a respective VCSEL interconnect 304a may be on each non-emitting VCSEL structure 124. Alternatively, less than all of the non-emitting VCSEL structures 124 may have VCSEL interconnects 304a thereon. The VCSEL interconnects 304a may be provided at a same height across the VCSEL device 200 (e.g., the VCSEL interconnects 304a may have a planar configuration) to aid flip-chip configuration, planarization, and wafer bonding, as described further in connection with FIG. 5.

The driver device 302 may include a plurality of driver interconnects 304b (i.e., interconnects connected to the driver device 302), such as copper posts, on a surface of the driver device 302. For example, the surface may be a redistribution layer 306 of the driver device 302 (e.g., that has a fan-in configuration or a fan-out configuration with respect to the pitch of the VCSEL mesa structures 100). Thus, the driver interconnects 304b may be electrically connected to respective traces of the redistribution layer 306. In some implementations, the driver device 302 may omit the redistribution layer 306. The driver interconnects 304b may be provided at a same height across the driver device 302 (e.g., the driver interconnects 304b may have a planar configuration) to aid flip-chip configuration, planarization, and wafer bonding, as described further in connection with FIG. 5. The VCSEL interconnects 304a may be bonded to the driver interconnects 304b, thereby forming interconnects between the VCSEL device 200 and the driver device 302.

As shown, an emission region and a connection region of the VCSEL apparatus 300 may be defined by the locations of the emitting VCSEL structures 122 and the locations of the non-emitting VCSEL structures 124. In operation, to activate an emitting VCSEL structure 122 (or multiple emitting VCSEL structures 122) in the emission region, the driver device 302 may cause current to flow, via an interconnect, to the emitting VCSEL structure 122. The current may flow to the second contact layer 128 for the emitting VCSEL structure 122, through the epitaxial layers 103, and to the first contact layer 126 (e.g., via the contact buffer layer 106). By locating the first contact layer 126 in close proximity to the mesa sidewall of the emitting VCSEL structure 122, electrical resistance in the VCSEL apparatus 300 is reduced. From the first contact layer 126, the current may flow into the first plating layer 130, which provides a path from the emission region to the connection region. For example, the current may flow through the first plating layer 130 across a non-emitting VCSEL structure 124 (e.g., without flowing through the epitaxial layers 103 for the non-emitting VCSEL structure 124) and to the driver device 302 via an interconnect connected to the first plating layer 130 at the non-emitting VCSEL structure 124.

As further shown, the VCSEL device 200 may include a first dielectric layer 308a that is filled around the VCSEL interconnects 304a. The first dielectric layer 308a may cover the additional layer structure 120. The VCSEL interconnects 304a may be exposed through openings in the first dielectric layer 308a, as described in connection with FIG. 5. Moreover, the first dielectric layer 308a may planarize the additional layer structure 120 to facilitate wafer bonding. The driver device 302 may include a second dielectric layer 308b that fills around the driver interconnects 304b. The second dielectric layer 308b may cover a surface of the driver device 302 (e.g., the redistribution layer 306). The driver interconnects 304b may be exposed through openings in the second dielectric layer 308b, as described in connection with FIG. 5. Moreover, the second dielectric layer 308b may planarize the surface of the driver device 302 to facilitate wafer bonding.

The first dielectric layer 308a and the second dielectric layer 308b may be composed of a dielectric material, as described herein. The first dielectric layer 308a may be bonded to the second dielectric layer 308b, thereby forming a single dielectric layer that fills an area between the VCSEL device 200 and the driver device 302 and provides mechanical support between the VCSEL device 200 and the driver device 302. Relative to an underfill material exhibiting poor coefficient of thermal expansion (CTE) matching between the VCSEL device 200 and the driver device 302, the dielectric layer may provide improved CTE matching between the VCSEL device 200 and the driver device 302, thereby reducing stress in the VCSEL apparatus 300 and improving manufacturing yield.

In some implementations, the driver device 302 may include a plurality of through silicon vias (TSVs) 310 that extend through the driver device 302 and electrically connect to contacts 312. The contacts 312 may electrically connect to the driver interconnects 304b (e.g., via the traces of the redistribution layer 306), thereby electrically connecting the TSVs 310 to the VCSEL device 200. For example, the TSVs 310 may have electrical connections to the additional layer structure 120 (e.g., via the driver interconnects 304b and the VCSEL interconnects 304a). For example, each emitting VCSEL structure 122 may be electrically connected to a respective TSV 310. In some implementations, the additional layer structure 120 over each non-emitting VCSEL structure 124 may be electrically connected to a respective TSV 310. Alternatively, the additional layer structure 120 over less than all of the non-emitting VCSEL structures 124 may have a corresponding TSV 310.

Moreover, the driver device 302 may include a plurality of electrical contacts 314 (e.g., pads) on a surface of the driver device 302 (e.g., an opposite surface from the surface with the driver interconnects 304b). The electrical contacts 314 are electrically connected to respective TSVs 310. Electrical contacts 314 in the emission region that are electrically connected to emitting VCSEL structures 122 may define anode contacts, and electrical contacts 314 in the connection region that are electrically connected to non-emitting VCSEL structures 124 may define cathode contacts. The electrical contacts 314 may be used, for example, to test an electrical connection between the driver device 302 and the VCSEL device 200 for each emitting VCSEL structure 122 and/or each non-emitting VCSEL structure 124. The electrical contacts 314 may also be part of a driving circuit for the driver device 302 or serve other purposes in the driver device 302. In some implementations, a dielectric layer may be deposited on the surface of the driver device 302 surrounding the electrical contacts 314.

In the emission region, the driver device 302 may include additional electrical structure to what is shown and described herein. The additional electrical structure may provide a particular desired control of the emitting VCSEL structures 122 (e.g., depending on a particular application for which the VCSEL apparatus 300 is to be used).

As indicated above, FIG. 3 is provided as an example. Other examples may differ from what is described with regard to FIG. 3.

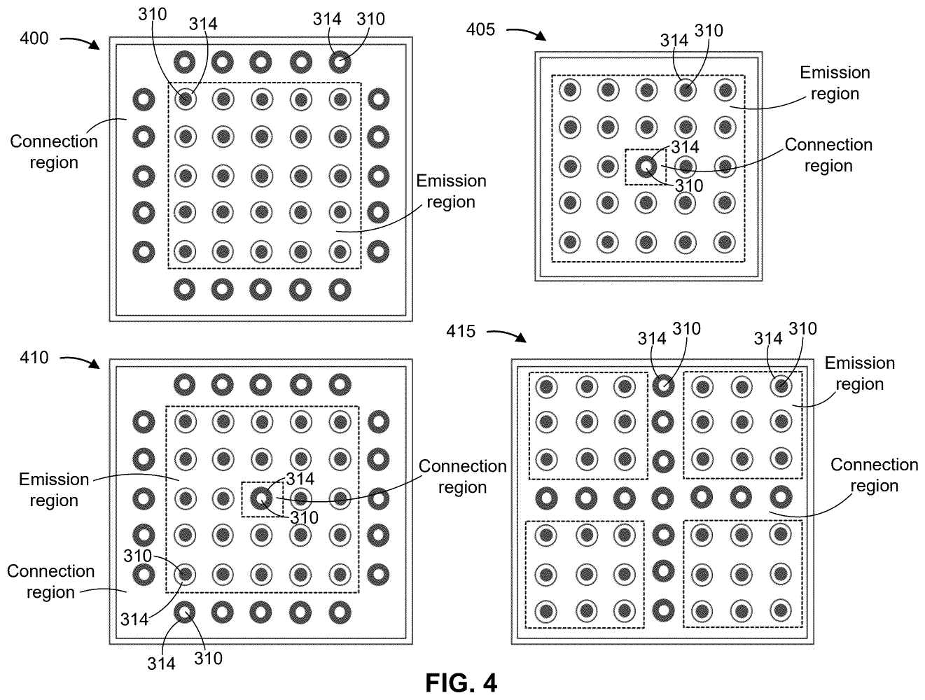

FIG. 4 illustrates examples 400, 405, 410, and 415 of locations of the TSVs 310 and the electrical contacts 314. For example, in examples 400, 405, 410, and 415, the surface of the driver device 302 that faces away from the VCSEL device 200 is shown. In some implementations, the locations of the TSVs 310 and the electrical contacts 314 in examples 400, 405, 410, and 415 may indicate the emission region and the connection region of the VCSEL apparatus 300, and therefore, may indicate an arrangement of the emitting VCSEL structures 122 and the non-emitting VCSEL structures 124.

In example 400, the anode electrical contacts 314 and associated TSVs 310 of the emission region may be confined within a perimeter defined by cathode electrical contacts 314 and associated TSVs 310 of the connection region. Thus, in some implementations, the emitting VCSEL structures 122 of the emission region may be confined within a perimeter defined by the non-emitting VCSEL structures 124 of the connection region.

In example 405, the cathode electrical contacts 314 and associated TSVs 310 of the connection region (shown as a single, centralized cathode electrical contact 314 and TSV 310) are confined within a perimeter defined by the anode electrical contacts 314 and associated TSVs 310 of the emission region. Thus, in some implementations, the non-emitting VCSEL structures 124 of the connection region (e.g., a single, centralized non-emitting VCSEL structure 124) may be confined within a perimeter defined by the emitting VCSEL structures 122 of the emission region. In this configuration, a VCSEL apparatus 300 may be made more compact.

In example 410, a first subset of the cathode electrical contacts 314 and associated TSVs 310 of the connection region (shown as a single, centralized cathode electrical contact 314 and TSV 310) are confined within a perimeter defined by the anode electrical contacts 314 and associated TSVs 310 of the emission region, and the anode electrical contacts 314 and associated TSVs 310 of the emission region are confined within a perimeter defined by a second subset of the cathode electrical contacts 314 and associated TSVs 310 of the connection region. Thus, in some implementations, a first subset of the non-emitting VCSEL structures 124 of the connection region are confined within a perimeter defined by the emitting VCSEL structures 122 of the emission region, and the emitting VCSEL structures 122 are confined within a perimeter defined by a second subset of the non-emitting VCSEL structures 124 of the connection region. Accordingly, the connection region may be split into two discrete regions, with the emission region between the two connection regions. In this configuration, a VCSEL apparatus 300 may exhibit a more uniform performance.

In example 415, the cathode electrical contacts 314 and associated TSVs 310 of the connection region may partition the anode electrical contacts 314 and associated TSVs 310 of the emission region into multiple subsets. Thus, in some implementations, the non-emitting VCSEL structures 124 of the connection region may partition the emitting VCSEL structures 122 of the emission region into multiple subsets. Accordingly, the emission region may be split into multiple discrete regions (e.g., four regions, as shown) that are separated from each other by the connection region.

As indicated above, FIG. 4 is provided as an example. Other examples may differ from what is described with regard to FIG. 4.

FIG. 5 is a diagram illustrating an example process 500 associated with manufacturing the VCSEL apparatus 300. In some implementations, one or more operations of process 500 may be performed by semiconductor manufacturing equipment and/or other manufacturing equipment. Process 500 is shown in FIG. 5 with respect to a single VCSEL device 200 and a single driver device 302. However, process 500 will be described herein with respect to a plurality of VCSEL devices 200 of a VCSEL wafer and a plurality of driver devices 302 of a driver wafer.

As shown by reference number 510, process 500 may include forming (e.g., plating) a plurality of VCSEL interconnects 304a (e.g., an interconnect plating layer) on one or more plating layers (e.g., the first plating layer 130 and/or the second plating layer 132) of the additional layer structure 120 that is disposed on a plurality of VCSEL mesa structures 100 of a plurality of VCSEL devices 200 of a VCSEL wafer 250. In some implementations, process 500 may include forming (e.g., plating) a plurality of driver interconnects 304b (e.g., an interconnect plating layer) on a plurality of driver devices 302 of a driver wafer 350. In some implementations, process 500 may include forming a redistribution layer 306 on the driver wafer 350, and the driver interconnects 304b may be formed on the redistribution layer 306. In some implementations, process 500 may include forming the VCSEL mesa structures 100 and/or the additional layer structure 120.

The VCSEL interconnects 304a and/or the driver interconnects 304b may include copper posts. In some implementations, the VCSEL interconnects 304a and/or the driver interconnects 304b may be from about 2 to about 3 μm tall. In some implementations, a seed layer (e.g., TiCu) may be applied (e.g., sputtered) to the VCSEL wafer 250 before the VCSEL interconnects 304a are formed and/or to the driver wafer 350 before the driver interconnects 304b are formed.

As shown by reference number 520, process 500 may include depositing a first dielectric layer 308a on the VCSEL devices 200. The first dielectric layer 308a may fill between the emitting VCSEL structures 122 and the non-emitting VCSEL structures 124 resulting in covering of the additional layer structure 120 and the VCSEL interconnects 304a. The first dielectric layer 308a provides passivation and a planar configuration of the VCSEL devices 200 to facilitate wafer bonding, as described below. Process 500 may also include depositing a second dielectric layer 308b on the driver devices 302 (e.g., the same dielectric material may be deposited on the VCSEL devices 200 and the driver devices 302). The second dielectric layer 308b may fill between the driver interconnects 304b and between any redistribution layers 306 or other structures on the driver devices 302 resulting in covering of the driver interconnects 304b. The second dielectric layer 308b provides passivation and a planar configuration of the driver devices 302 to facilitate wafer bonding, as described below.

The first dielectric layer 308a and/or the second dielectric layer 308b may be composed of a passivation dielectric, such as SiO₂ or SiN. The first dielectric layer 308a and/or the second dielectric layer 308b may be deposited in multiple layers. For example, depositing the first dielectric layer 308a may include multiple iterations of applying an SOG coat to the VCSEL wafer 250 and curing the VCSEL wafer 250 in an oven (e.g., until dielectric fills between the emitting VCSEL structures 122 and the non-emitting VCSEL structures 124, and covers the VCSEL devices 200). Similarly, depositing the second dielectric layer 308b may include multiple iterations of applying an SOG coat to the driver wafer 350 and curing the driver wafer 350 in an oven (e.g., until dielectric fills between the driver interconnects 304b and between any redistribution layers 306 or other structures on the driver devices 302, and covers the driver devices 302). In some implementations, each SOG coat may be polished following curing to provide planarization, as described below.

As shown by reference number 530, process 500 may include planarizing the first dielectric layer 308a to expose the VCSEL interconnects 304a through the first dielectric layer 308a, and the second dielectric layer 308b to expose the driver interconnects 304b through the second dielectric layer 308b. In some implementations, each of the VCSEL interconnects 304a in emission regions may be exposed by the planarizing. In some implementations, each of the VCSEL interconnects 304a in connection regions may be exposed or a subset of the VCSEL interconnects 304a in connection regions may be exposed.

Planarizing the first dielectric layer 308a may include polishing the first dielectric layer 308a (e.g., the SOG coat) using chemical mechanical polishing (CMP) until the VCSEL interconnects 304a are exposed, followed by depositing a thin layer of additional dielectric material and polishing again, which may be repeated multiple times until the surface of the first dielectric layer 308a is flat (e.g., within a particular tolerance). As a result of this procedure, the VCSEL interconnects 304a may be exposed, forming a dishing (e.g., concave) surface topography on the VCSEL wafer 250. Planarizing the second dielectric layer 308b may be performed using a similar procedure as described above. In some implementations, the polishing and planarizing of the first dielectric layer 308a and/or the second dielectric layer 308b may be performed as part of the deposition of the first dielectric layer 308a and/or the second dielectric layer 308b in multiple layers (e.g., by sequentially depositing dielectric layers and polishing), as described above. Rather than using a complex die level underfilling to mechanically support a VCSEL apparatus 300, the steps of depositing and planarizing the dielectric layers 308a, 308b respectively on the VCSEL wafer 250 and the driver wafer 350 simplify the manufacturing process and enable wafer level bonding that improves manufacturing yield.

As shown by reference number 540, process 500 may include bonding the VCSEL wafer 250 and the driver wafer 350 (e.g., using fusion bonding) to obtain a bonded VCSEL wafer and driver wafer. The VCSEL interconnects 304a may be bonded to the driver interconnects 304b in the bonded VCSEL wafer and driver wafer (e.g., forming the interconnects 304 between the VCSEL wafer 250 and the driver wafer 350). Moreover, the first dielectric layer 308a may be bonded to the second dielectric layer 308b in the bonded VCSEL wafer and driver wafer. Bonding the VCSEL wafer 250 and the driver wafer 350 may include arranging the VCSEL wafer 250 in a flip-chip configuration to the driver wafer 350 and aligning the VCSEL interconnects 304a with the driver interconnects 304b, followed by bonding the VCSEL wafer 250 and the driver wafer 350 together.

In some implementations, bonding the VCSEL wafer 250 and the driver wafer 350 may include treating the dielectric layers 308a, 308b with O₂ and/or N₂ plasma gas to activate the dielectric material for fusion bonding. In some implementations, the VCSEL wafer 250 and the driver wafer 350 may be clamped together and put into an oven for slow annealing.

As shown by reference number 550, process 500 may include thinning the bonded VCSEL wafer and driver wafer (e.g., at the VCSEL wafer side and/or the driver wafer side). In some implementations, process 500 may include forming a plurality of TSVs 310 in the driver wafer 350 (e.g., which may be performed prior to or after any of the aforementioned steps of process 500), such that each TSV 310 is electrically connected to a respective driver interconnect 304b. In some implementations, process 500 may include forming a plurality of electrical contacts 314 on a surface of the driver wafer 350 that electrically connect to respective TSVs 310 (e.g., which may be performed prior to or after any of the aforementioned steps of process 500 after the TSVs 310 are formed). As an example, the TSVs 310 and/or the electrical contacts 314 may be formed after bonding the VCSEL wafer 250 and the driver wafer 350, such as after thinning the bonded VCSEL wafer and driver wafer. In some implementations, the bonded VCSEL wafer and driver wafer may be singulated to obtain a plurality of VCSEL apparatuses 300.

Although FIG. 5 describes example operations of process 500, in some implementations, process 500 includes additional operations, fewer operations, different operations, or differently arranged operations than those depicted in FIG. 5. Additionally, or alternatively, two or more of the operations of process 500 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “top,” “bottom,” “front,” “back,” “above,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical cavity surface emitting laser (VCSEL) device, comprising:
a substrate;
a set of epitaxial layers, disposed on the substrate, defining a plurality of VCSEL mesa structures, wherein each of the plurality of VCSEL mesa structures has a top surface and a sidewall; and
an additional layer structure disposed on the set of epitaxial layers,
wherein the additional layer structure configures the plurality of VCSEL mesa structures into a set of emitting VCSEL structures, for backside emission through the substrate, and a set of non-emitting VCSEL structures,
wherein the additional layer structure comprises a first contact layer on the set of epitaxial layers at a base of the plurality of VCSEL mesa structures and surrounding each of the plurality of VCSEL mesa structures, and a second contact layer on top surfaces of the set of emitting VCSEL structures,
wherein the additional layer structure has a first layer composition, for the set of emitting VCSEL structures, that allows current flow between the first contact layer and the second contact layer through the set of epitaxial layers, and
wherein the additional layer structure has a second layer composition, for the set of non-emitting VCSEL structures, that allows current flow over top surfaces of the non-emitting VCSEL structures to the first contact layer and disallows current flow through the set of epitaxial layers.

2. The VCSEL device of claim 1, wherein the plurality of VCSEL mesa structures project from a contact buffer layer of the set of epitaxial layers.

3. The VCSEL device of claim 1, wherein the additional layer structure, for the set of emitting VCSEL structures, further comprises:
a first plating layer on the first contact layer;
a second plating layer on the second contact layer; and
one or more passivation layers isolating the first plating layer from the set of epitaxial layers and isolating the first plating layer from the second plating layer.

4. The VCSEL device of claim 1, wherein the additional layer structure, for the set of non-emitting VCSEL structures, further comprises:
a plating layer on the first contact layer, along the sidewall and extending over top surfaces of the non-emitting VCSEL structures; and
one or more passivation layers isolating the plating layer from the set of epitaxial layers.

5. The VCSEL device of claim 1, wherein a minimum separation between the first contact layer and sidewalls of the plurality of VCSEL mesa structures is less than a pitch of the plurality of VCSEL mesa structures.

6. The VCSEL device of claim 1, wherein a gap between the first contact layer and sidewalls of the plurality of VCSEL mesa structures is at most 3 micrometers.

7. The VCSEL device of claim 1, further comprising:
a plurality of interconnects electrically connected to one or more plating layers of the additional layer structure on respective top surfaces of the set of emitting VCSEL structures and the set of non-emitting VCSEL structures,
wherein the plurality of interconnects and the one or more plating layers define respective electrodes for the set of emitting VCSEL structures and respective opposite electrodes for the set of non-emitting VCSEL structures.

8. The VCSEL device of claim 7, further comprising:
a dielectric layer planarizing the additional layer structure,
wherein the plurality of interconnects are exposed through openings in the dielectric layer.

9. The VCSEL device of claim 1, wherein the set of emitting VCSEL structures are confined within a perimeter defined by the set of non-emitting VCSEL structures.

10. An addressable vertical cavity surface emitting laser (VCSEL) apparatus comprising:
a VCSEL device, comprising:
a substrate;
a set of epitaxial layers, disposed on the substrate, defining a plurality of VCSEL mesa structures;
an additional layer structure disposed on the set of epitaxial layers, wherein the additional layer structure configures the plurality of VCSEL mesa structures into a set of emitting VCSEL structures, for backside emission through the substrate, and a set of non-emitting VCSEL structures;
a plurality of VCSEL interconnects electrically connected to one or more plating layers of the additional layer structure on respective top surfaces of the set of emitting VCSEL structures and the set of non-emitting VCSEL structures, wherein the plurality of VCSEL interconnects and the one or more plating layers define respective electrodes for the set of emitting VCSEL structures and respective opposite electrodes for the set of non-emitting VCSEL structures; and
a first dielectric covering the additional layer structure, wherein the plurality of VCSEL interconnects are exposed through openings in the first dielectric; and
a driver device, for the VCSEL device, comprising:
a plurality of driver interconnects on a surface of the driver device; and
a second dielectric covering the surface, wherein the plurality of driver interconnects are exposed through openings in the second dielectric,
wherein the plurality of driver interconnects are bonded to the plurality of VCSEL interconnects.

11. The addressable VCSEL apparatus of claim 10, wherein the additional layer structure has a first layer composition for the set of emitting VCSEL structures and a second layer composition for the set of non-emitting VCSEL structures,
wherein the first layer composition and the second layer composition comprise a first contact layer on the set of epitaxial layers at a base of the plurality of VCSEL mesa structures and surrounding each of the plurality of VCSEL mesa structures,
wherein the first layer composition further comprises a second contact layer electrically connected to the top surfaces of the set of emitting VCSEL structures, and
wherein the second layer composition prevents electrical connection to the top surfaces of the set of non-emitting VCSEL structures.

12. The addressable VCSEL apparatus of claim 11, wherein the first layer composition electrically connects the first contact layer to the second contact layer through the set of epitaxial layers, and
wherein the second layer composition electrically connects over and around the non-emitting VCSEL structures to the first contact layer.

13. The addressable VCSEL apparatus of claim 11, wherein the first layer composition further comprises:
a first plating layer on the first contact layer;
a second plating layer on the second contact layer,
wherein VCSEL interconnects, of the plurality of VCSEL interconnects, that are on the set of emitting VCSEL structures are electrically connected to the second plating layer; and
one or more passivation layers isolating the first plating layer from the set of epitaxial layers and isolating the first plating layer from the second plating layer.

14. The addressable VCSEL apparatus of claim 11, wherein the second layer composition further comprises:
a plating layer on the first contact layer and extending over top surfaces of the non-emitting VCSEL structures,
wherein VCSEL interconnects, of the plurality of VCSEL interconnects, that are on the set of non-emitting VCSEL structures are electrically connected to the plating layer; and
one or more passivation layers isolating the plating layer from the set of epitaxial layers and isolating the plating layer from the top surfaces of the non-emitting VCSEL structures.

15. The addressable VCSEL apparatus of claim 10, wherein the driver device further comprises:
a plurality of through silicon vias (TSVs) extending through the driver device and electrically connected to respective driver interconnects of the plurality of driver interconnects; and
a plurality of electrical contacts on an opposite surface of the driver device and electrically connected to respective TSVs of the plurality of TSVs.

16. The addressable VCSEL apparatus of claim 10, wherein the surface of the driver device is a redistribution layer.

17. A method, comprising:
forming a plurality of VCSEL interconnects on one or more plating layers of an additional layer structure disposed on a plurality of VCSEL mesa structures of a plurality of VCSEL devices of a VCSEL wafer,
wherein the additional layer structure configures the plurality of VCSEL mesa structures into a set of emitting VCSEL structures and a set of non-emitting VCSEL structures, and
wherein the plurality of VCSEL interconnects and the one or more plating layers define respective electrodes for the set of emitting VCSEL structures and respective opposite electrodes for the set of non-emitting VCSEL structures;
depositing a first dielectric on the plurality of VCSEL devices, and a second dielectric on a plurality of driver devices of a driver wafer;
planarizing the first dielectric to expose the plurality of VCSEL interconnects through the first dielectric, and the second dielectric to expose a plurality of driver interconnects, of the plurality of driver devices, through the second dielectric; and
bonding the VCSEL wafer to the driver wafer to obtain a bonded VCSEL wafer and driver wafer,
wherein the plurality of VCSEL interconnects are bonded to the plurality of driver interconnects in the bonded VCSEL wafer and driver wafer.

18. The method of claim 17, further comprising:
singulating the bonded VCSEL wafer and driver wafer to obtain a plurality of addressable VCSEL apparatuses.

19. The method of claim 17, further comprising:
forming a plurality of through silicon vias (TSVs) in the driver wafer, wherein each TSV is electrically connected to respective driver interconnects of the plurality of driver interconnects; and
forming a plurality of electrical contacts on a surface of the driver wafer that electrically connect to respective TSVs of the plurality of TSVs.

20. The method of claim 17, further comprising:
forming a redistribution layer on the driver wafer; and
forming the plurality of driver interconnects on the redistribution layer.
